(19) United States
(12) Patent Application Publication
(10) Pub. No.: US 2007/0141769 A1
(43) Pub. Date: Jun. 21, 2007

(54) Method of manufacturing flash memory device

(75) Inventor: Byoung Ki Lee, Icheon-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 11/491,589

(22) Filed: Jul. 24, 2006

(30) Foreign Application Priority Data
Dec. 20, 2005 (KR) 2005-126154

(51) Int. Cl. H01L 21/8234; H01L 21/336

(52) U.S. Cl. 438/197

(57) ABSTRACT

A method of manufacturing a flash memory device, including the steps of sequentially forming a tunnel oxide film, a first polysilicon layer, a nitride film, and a hard mask film on a semiconductor substrate, etching the hard mask film, the nitride film, the first polysilicon layer, and a predetermined region of the tunnel oxide films and then etching the exposed semiconductor substrate by a predetermined depth, thereby forming trenches, forming an oxide film on the entire structure so that the trenches are buried, polishing the oxide film and stripping the hard mask film, forming isolation films, etching the isolation films by a predetermined thickness, wherein when the nitride film is etched, the first polysilicon layer is also etched to form a trapezoid profile, stripping the nitride film remaining after the nitride film is etched, and forming a dielectric layer, and burying the entire top surface with a second polysilicon layer and a gate conductive film.

### BACKGROUND

1. Field of the Invention

The invention relates generally to a method of manufacturing a semiconductor memory device and, more particularly, to a method of manufacturing a flash memory device wherein etching is facilitated by changing the profile of the gate.

2. Discussion of Related Art

The existing NOR flash memory device has many limits to its program speed. To overcome the limits, NAND flash memory devices have been proposed which can perform a data program by injecting electrons into the floating gate by Fowler-Nordheim (FN) tunneling and can provide a large capacity and high integration.

A NAND flash memory device includes a plurality of cell blocks. One cell block includes a plurality of cell strings in which a plurality of cells for storing data are connected in series to form one string, and a drain select transistor and a source select transistor formed between the cell string and the drain, and the cell string and the source, respectively.

The cell of the NAND flash memory device is formed by forming an isolation film on a given region of a semiconductor substrate, forming a gate in which a tunnel oxide film, a floating gate, a dielectric layer, and a control gate are laminated on a given region on the semiconductor substrate, and forming junction units at both sides of the gate.

The dielectric layer is formed along the profile of the underlying floating gate. The dielectric layer formed of SiO₂, Si₃N₄, or SiO₂ in the related art can be easily etched using an F-based dry etch gas by means of reactive ion enhanced (RIE) etch equipment. At this time, if the dielectric layer is formed of a high dielectric (K) material instead of Si₃N₄ in order to improve the characteristics of the cell, RIE etching is almost impossible. This is because the high-K material contains a highly stabilize compound since it has a strong inter-atomic coupling. Therefore, the dielectric layer formed of Al₂O₃, ZrO₂, HfO₂ or the like is etched by the sputtering method.

Meanwhile, the sputter yield (i.e., the ratio of the number of emitted gas atoms to the number of gas ions incident in the sputtering method) varies depending on the angle of incidence of the ion. The sputter yield has the best value when the incident angle of ion ranges from 60 to 70 degrees, but is significantly low when the incident angle is 80 or more degrees. In this case, sputtering is rarely generated.

Accordingly, the dielectric layer formed along the floating gate has sidewalls whose angle is almost close to 90 degrees. Therefore, if Al₂O₃, ZrO₂, HfO₂ or the like (i.e., the high-K material) is used instead of Si₃N₄, it is almost impossible to etch the dielectric layer.

### SUMMARY OF THE INVENTION

In one embodiment, the invention provides a method of manufacturing a flash memory device, wherein the sputtering method can be used in order to etch a dielectric layer formed of a high dielectric material and a stack type gate pattern can be easily formed by changing the profile of a floating gate so that sputtering is activated.

According to one embodiment, the invention provides a method of manufacturing a flash memory device, including the steps of sequentially forming a tunnel oxide film, a first polysilicon layer, a nitride film, and a hard mask film on a semiconductor substrate; etching the hard mask film, the nitride film, the first polysilicon layer, and a predetermined region of the tunnel oxide film and then etching the exposed semiconductor substrate by a predetermined depth, thereby forming trenches; forming an oxide film on the entire structure so that the trenches are buried, polishing the oxide film and stripping the hard mask film, forming isolation films; etching the isolation films by a predetermined thickness, wherein when the nitride film is etched, the first polysilicon layer is also etched to form a trapezoid profile; stripping the nitride film remaining after the nitride film is etched, and forming a dielectric layer; and, burying the entire top surface with a second polysilicon layer and a gate conductive film.

The first polysilicon layer may preferably be formed to a thickness of 800 Å to 1200 Å.

The first polysilicon layer may preferably be formed by laminating an undoped film having a thickness of 200 Å to 400 Å and a doped film having a thickness of 400 Å to 800 Å.

The nitride film may preferably be formed to a thickness of 300 Å to 500 Å.

The hard mask film may preferably be formed by sequentially laminating an oxide film, amorphous carbon, and SiON.

When the oxide film is polished, the nitride film, preferably of 200 Å to 400 Å in thickness, may be polished so that a nitride film of 100 Å to 200 Å in thickness remains on the first polysilicon layer.

The isolation film may preferably be formed to have a height of 200 Å to 300 Å from the semiconductor substrate.

The etch process of the nitride film may preferably be performed by applying a source power of 200 W to 500 W and a bias power of 100 W to 200 W and injecting HBr of 50 sccm to 200 sccm, Cl₂ of 10 sccm to 100 sccm, and O₂ of 0 to 10 sccm in an etch chamber in which the pressure of 5 mTorr to 50 mTorr is maintained.

When the nitride film is etched, the first polysilicon layer may preferably form a profile having a good sputter yield.

The nitride film may preferably be etched using etch equipment such as capacitive coupled plasma (CCP) or inductively coupled plasma (ICP).

The dielectric layer may preferably have a lamination structure of SiO₂, Si₃N₄, and SiO₂, and may preferably be formed using a high dielectric material (any one of Al₂O₃, ZrO₂, and HfO₂) instead of Si₃N₄ or a mixture gas of ZrO₂ and HfO₂.

### BRIEF DESCRIPTION OF THE DRAWINGS

A more compete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIGS. 1 to 5 are cross-sectional views illustrating a method of manufacturing a flash memory device according to an embodiment of the invention.

### DETAILED DESCRIPTION OF EMBODIMENTS

The invention will now be described in detail in connection with certain exemplary embodiments with reference to the accompanying drawings.

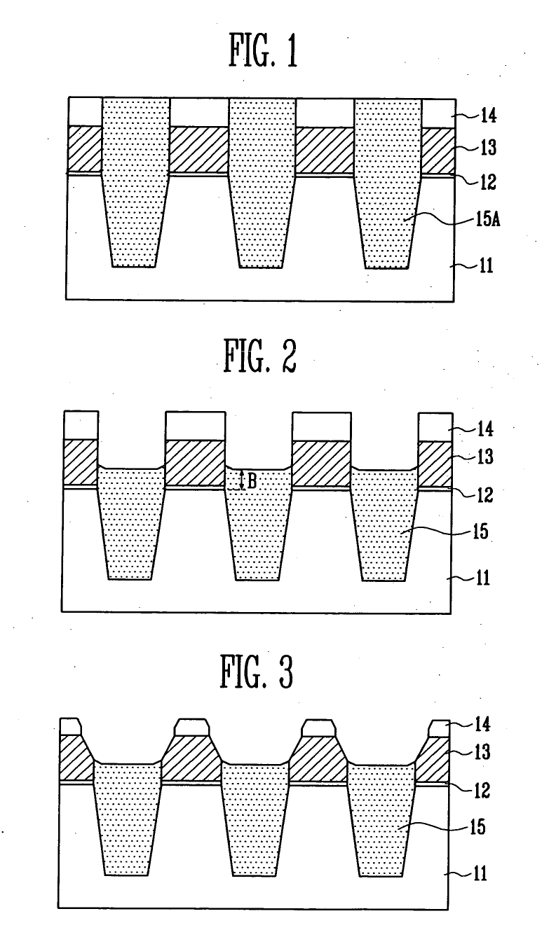

FIGS. 1 to 5 are cross-sectional views illustrating a method of manufacturing a flash memory device according to an embodiment of the invention.

Referring to FIG. 1, a tunnel oxide film 12, a first polysilicon layer 13, a nitride film 14, and a hard mask film (not shown) are sequentially formed on a semiconductor substrate 11.

The first polysilicon layer 13 has a lamination structure of an undoped film and a doped film. The undoped film may preferably be formed to a thickness of 200 Å to 400 Å and the doped film may preferably be formed to a thickness of 400 Å to 800 Å. The nitride film 14 may preferably be formed to a thickness of 300 Å to 500 Å. Furthermore, the hard mask film is preferably formed by sequentially laminating an oxide film, amorphous carbon, and SiON.

After the hard mask film (not shown) is patterned by photo and etch processes employing an isolation mask, the nitride film 14, the first polysilicon layer 13, the tunnel oxide film 12, and the semiconductor substrate 11 of a predetermined depth are etched to form trenches.

Oxide films 15A are formed on the entire structure so that the trenches are buried. The oxide films 15A are polished by chemical mechanical polishing (CMP) until the nitride film 14 is exposed. During the CMP process, the nitride film is preferably polished to a thickness of 200 Å to 400 Å, so that the nitride film of 100 Å to 200 Å in thickness remains on the first polysilicon layer 13.

Referring to FIG. 2, the oxide film 15A is etched by a predetermined depth using a solution containing HF, thereby forming isolation films 15. The isolation films 15 may preferably be formed to have a height of 200 Å to 300 Å from the semiconductor substrate 11.

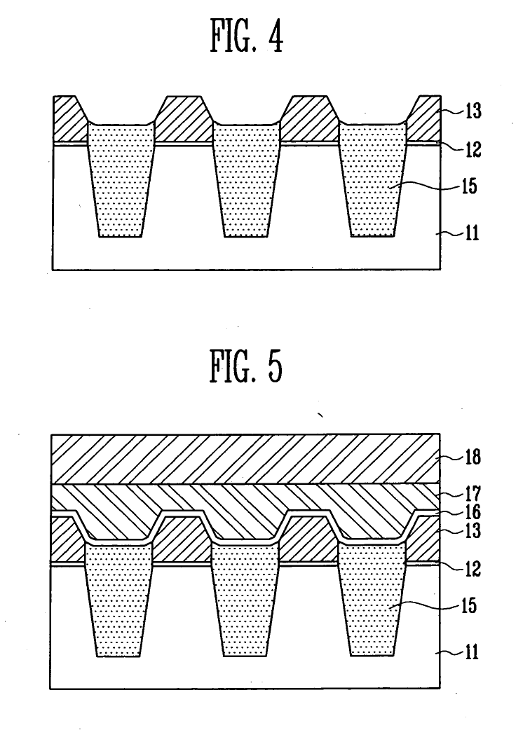

Referring to FIG. 3, the nitride film 14 is etched preferably using dry etch. The etch conditions may preferably include applying a source power of 200 W to 500 W and a bias power of 100 W to 200 W and injecting HBr of 50 sccm to 200 sccm, Cl₂ of 10 sccm to 100 sccm, and O₂ of 0 to 10 sccm in an etch chamber in which the pressure of 5 mTorr to 50 mTorr is maintained.

If the etching is performed under the above conditions, the first polysilicon layer 13 is also etched. The etching begins from the sidewall edges to form a trapezoid profile. This enhances the sputter yield sputter yield (i.e., the ratio of the number of emitted gas atoms to the number of gas ions incident in the sputtering method). The sputter yield is varied depending on the incident angle of ion. The sputter yield has the best value when the incident angle of ion ranges from 60 degrees to 70 degrees, but is significantly low when the incident angle is 80 or more degrees. In this case, sputtering is rarely generated.

Therefore, if the first polysilicon layer has the trapezoid profile, the incident angle becomes 60 degrees to 70 degrees and the activation of sputtering can be improved accordingly.

Referring to FIG. 4, the remaining nitride film 14 is stripped preferably using a phosphoric acid solution.

Referring to FIG. 5, after a dielectric layer 16 is formed, a second polysilicon layer 17 and a gate conductive film 18 are formed. The dielectric layer 16 may be formed in order of SiO₂, a high dielectric material, and SiO₂. Al₂O₃, or ZrO₂ or HfO₂ or a mixture thereof may be used as the high dielectric raw material.

As described above, according to the invention, in the manufacture process of the NAND flash memory device, the characteristics of the film can be improved since the high dielectric material is used as the raw material of the dielectric layer.

Furthermore, the sputter yield can be enhanced by changing the profile of the first polysilicon layer in order to etch the high dielectric layer. Accordingly, the dielectric layer can be etched very easily and subsequent processes can be facilitated.

While the invention has been described in connection with practical exemplary embodiments the invention is not limited to the disclosed embodiments but, to the contrary, is intended to cover various modifications and equivalent arrangements included within the spirit and scope of the appended claims.

What is claimed is:

1. A method of manufacturing a flash memory device semiconductor device, the method comprising the steps of:
sequentially forming a tunnel oxide film, a first polysilicon layer, a nitride film, and a hard mask film on a semiconductor substrate;
etching the hard mask film, the nitride film, the first polysilicon layer, and a predetermined region of the tunnel oxide film and then etching the exposed semiconductor substrate by a predetermined depth, thereby forming trenches;
forming an oxide film on the entire structure so that the trenches are buried, polishing the oxide film and stripping the hard mask film, forming isolation films;
etching the isolation films by a predetermined thickness, wherein when the nitride film is etched, the first polysilicon layer is also etched to form a trapezoid profile;
stripping the nitride film remaining after the nitride film is etched, and forming a dielectric layer; and
burying the entire top surface with a second polysilicon layer and a gate conductive film.

2. The method of claim 1, comprising forming the first polysilicon layer to a thickness of 800 Å to 1200 Å.

3. The method of claim 1, comprising forming the first polysilicon layer by laminating an undoped film having a thickness of 200 Å to 400 Å and a doped film having a thickness of 400 Å to 800 Å.

4. The method of claim 1, comprising forming the nitride film to a thickness of 300 Å to 500 Å.

5. The method of claim 1, comprising forming the hard mask film by sequentially laminating an oxide films, amorphous carbon, and SiON.

6. The method of claim 1, comprising polishing the oxide film and polishing the nitride film of 200 Å to 400 Å in thickness so that the nitride film of 100 Å to 200 Å in thickness remains on the first polysilicon layer.

7. The method of claim 1, comprising forming the isolation film to have a height of 200 Å to 300 Å from the semiconductor substrate.

8. The method of claim 1, comprising performing the etch process of the nitride film by applying a source power of 200 W to 500 W and a bias power of 100 W to 200 W and injecting HBr of 50 sccm to 200 sccm, Cl₂ of 10 sccm to 100 sccm, and O₂ of 0 to 10 sccm in an etch chamber in which the pressure of 5 mTorr to 50 mTorr is maintained.

9. The method of claim 1, wherein when the nitride film is etched, the first polysilicon layer forms a profile having a good sputter yield.

10. The method of claim 1, comprising etching the nitride film using etch equipment selected from the group consisting of capacitive coupled plasma and inductively coupled plasma.

11. The method of claim 1, wherein the dielectric layer has a lamination structure of SiO₂, Si₃N₄, and SiO₂, and is formed using a high dielectric material selected from the group consisting of Al₂O₃, ZrO₂, and HfO₂.
